(19) United States
(12) Patent Application Publication
(10) Pub. No.: US 2026/0214998 A1
(43) Pub. Date: Jul. 23, 2026

(54) ELECTROSTATIC DISCHARGE STRUCTURE

(71) Applicant: Vanguard International Semiconductor Corporation, Hsinchu (TW)

(72) Inventors: Ting-Yu CHANG, Zhubei City (TW); Jian-Hsing LEE, Hsinchu City (TW); Yeh-Ning JOU, Hsinchu City (TW); Chih-Hsuan LIN, Hsinchu City (TW); Chieh-Yao CHUANG, Kaohsiung City (TW); Hsien-Feng LIAO, Taichung City (TW)

(73) Assignee: Vanguard International Semiconductor Corporation, Hsinchu (TW)

(21) Appl. No.: 19/027,981

(22) Filed: Jan. 17, 2025

(51) Int. Cl. H10D 89/60

(52) U.S. Cl. CPC H10D 89/713

(57) ABSTRACT

An electrostatic discharge structure including a substrate, a deep well, a first doped region, a first floating structure, a first ring-shaped structure, a first interconnection structure, and a second interconnection structure is provided. The substrate has the first conductivity type. The deep well is disposed in the substrate and has the second conductivity type. The doped region is disposed on the deep well and has the first conductivity type. The floating structure is disposed on the deep well. The floating structure includes a first region and has the first conductivity type. The ring-shaped structure surrounds the floating structure. The first interconnection structure is electrically connected to the doped region. The second interconnection structure is electrically connected to the ring-shaped structure. The first doped region is disposed in the first region. The voltage level of the floating structure is a floating level.

### BACKGROUND OF THE INVENTION

### Field of the Invention

The present invention relates to as an electrostatic discharge (ESD) structure, and, in particular, it relates to an ESD structure with a bidirectional discharge structure.

### Description of the Related Art

As the process of manufacturing semiconductors has developed, electrostatic discharge (ESD) protection has become one of the most critical reliability issues for integrated circuits (IC). In particular, as semiconductor processing advances into the deep sub-micron stage, scaled-down devices and thinner gate oxides are becoming more vulnerable to ESD stress.

### BRIEF SUMMARY OF THE INVENTION

In accordance with an embodiment of the disclosure, an electrostatic discharge structure comprises a substrate, a deep well, a first doped region, a first floating structure, a first ring-shaped structure, a first interconnection structure, and a second interconnection structure. The substrate has the first conductivity type. The deep well is disposed in the substrate and has the second conductivity type. The doped region is disposed on the deep well and has the first conductivity type. The floating structure is disposed on the deep well, comprises a first region, and has the first conductivity type. The ring-shaped structure surrounds the floating structure. The first interconnection structure is electrically connected to the doped region. The second interconnection structure is electrically connected to the ring-shaped structure. The first doped region is disposed in the first region. The voltage level of the floating structure is a floating level.

### BRIEF DESCRIPTION OF THE DRAWINGS

The present invention can be more fully understood by reading the subsequent detailed description and examples with references made to the accompanying drawings, wherein:

FIG. 1A is a plan view of an exemplary embodiment of an electrostatic discharge (ESD) structure in accordance with some embodiments of the disclosure.

FIG. 1B is a cross-sectional view taken alone a line A-A′ of FIG. 1A.

FIG. 1C is an equivalent circuit of an exemplary embodiment of the ESD structure according to various aspects of the present disclosure.

FIG. 1D is an equivalent circuit of another exemplary embodiment of the ESD structure according to various aspects of the present disclosure.

FIG. 2A is a plan view of another exemplary embodiment of the ESD structure in accordance with some embodiments of the disclosure.

FIG. 2B is a cross-sectional view taken alone a line B-B′ of FIG. 2A.

FIG. 3A~3C are plan views of other exemplary embodiments of the ESD structure in accordance with some embodiments of the disclosure.

FIG. 4A~4C are plan views of other exemplary embodiments of the ESD structure in accordance with some embodiments of the disclosure.

FIG. 5A~5C are plan views of other exemplary embodiments of the ESD structure in accordance with some embodiments of the disclosure.

FIG. 6A is a cross-sectional view taken alone a line C-C′ of FIG. 5C.

FIG. 6B is a cross-sectional view taken alone a line D-D′ of FIG. 5C.

FIGS. 7A and 7B are equivalent circuits of other exemplary embodiments of the ESD structure of FIG. 5C according to various aspects of the present disclosure.

FIGS. 8A and 8B are equivalent circuits of other exemplary embodiments of the ESD structure of FIG. 5C according to various aspects of the present disclosure.

FIGS. 9A and 9B are equivalent circuits of other exemplary embodiments of the ESD structure of FIG. 5C according to various aspects of the present disclosure.

FIGS. 10A and 10B are equivalent circuits of other exemplary embodiments of the ESD structure of FIG. 5C according to various aspects of the present disclosure.

### DETAILED DESCRIPTION OF THE INVENTION

The present invention will be described with respect to particular embodiments and with reference to certain drawings, but the invention is not limited thereto and is only limited by the claims. The drawings described are only schematic and are non-limiting. In the drawings, the size of some of the elements may be exaggerated for illustrative purposes and not drawn to scale. The dimensions and the relative dimensions do not correspond to actual dimensions in the practice of the invention.

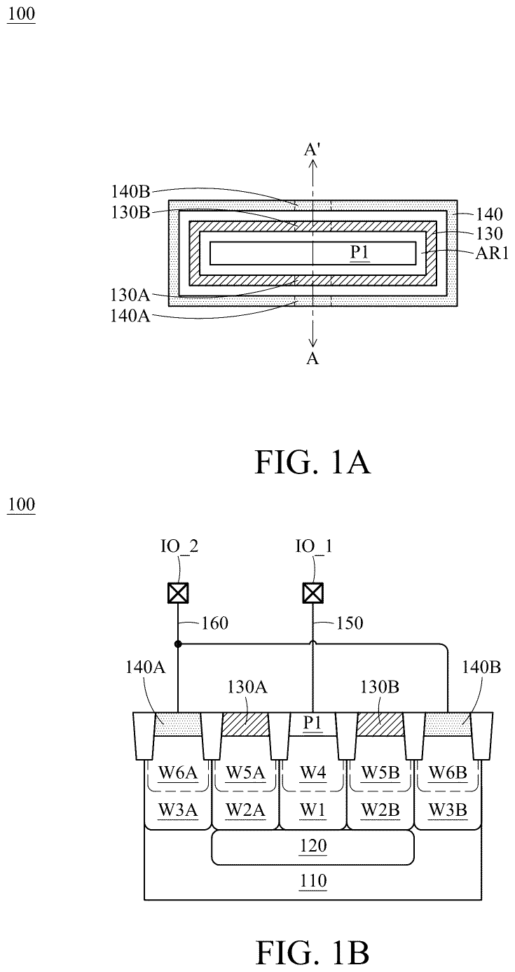

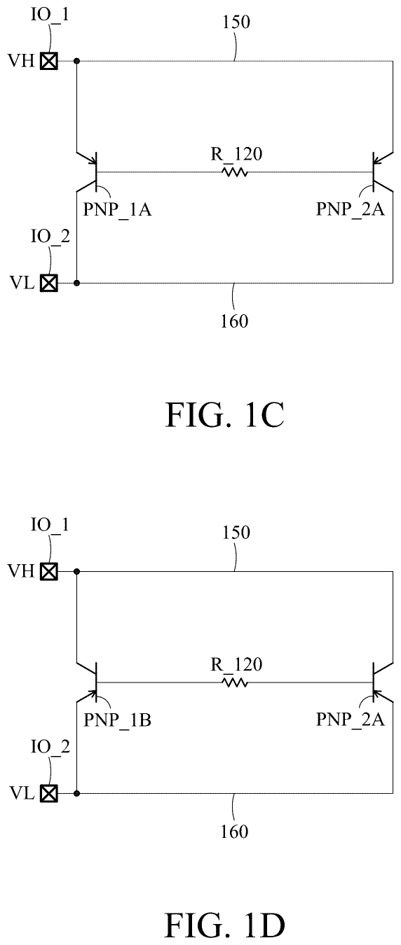

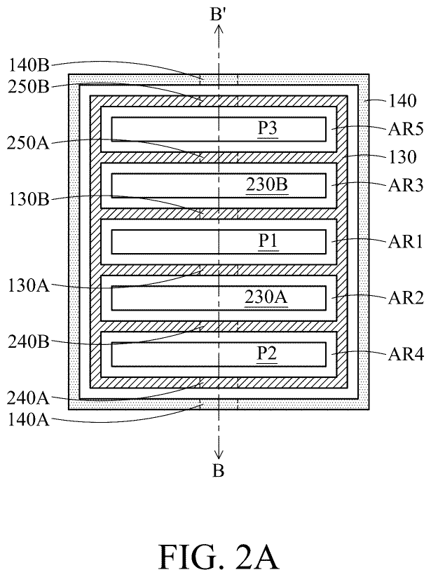

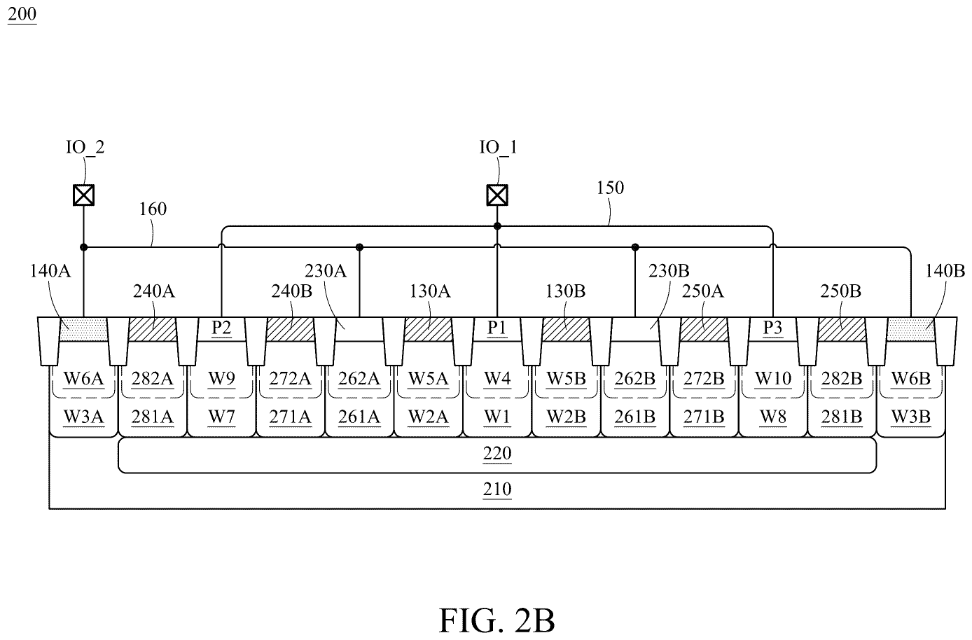

FIG. 1A is a plan view of an exemplary embodiment of an electrostatic discharge (ESD) structure in accordance with some embodiments of the disclosure. FIG. 1B is a cross-sectional view taken alone a line A-A′ of FIG. 1A. As shown in FIG. 1B, the ESD structure 100 comprises a substrate 110, a deep well 120, and doped regions P1, 130A, 130B, 140A, and 140B. The substrate 110 has the first conductivity type. The doped region 120 is disposed in the substrate 110 and has the second conductivity type. The second conductivity type is different from the first conductivity type. In one embodiment, the first conductivity type is P-type and the second conductivity type is N-type. In another embodiment, the first conductivity type is N-type and the second conductivity type is P-type.

The doped region P1 is disposed in the deep well 120 and has the first conductivity type. In one embodiment, the doped concentration of the doped region P1 is higher than the doped concentration of the substrate 110. The doped regions 130A and 130B are disposed in the deep well 120. The doped regions 130A and 130B have the first conductivity type. In one embodiment, the doped concentrations of the doped regions 130A and 130B are similar to the doped concentration of the doped region P1. In some embodiments, the doped regions 130A and 130B form a floating structure 130. In this embodiment, the voltage levels of the doped regions 130A and 130B are a floating level.

The doped regions 140A and 140B are disposed in the substrate 110. The doped regions 140A and 140B have the first conductivity type. In one embodiment, the doped concentrations of the doped regions 140A and 140B are similar to the doped concentration of the doped region P1. In some embodiments, the doped regions 140A and 140B form a floating structure 140.

In some embodiments, the ESD structure 100 further comprises wells W1, W2A, W2B, W3A, and W3B. The well W1 is disposed on the deep well 120 and has the first conductivity type. In this case, the doped region P1 is disposed in the well W1. In one embodiment, the doped concentration of the doped region P1 is higher than the doped concentration of the well W1, and the doped concentration of the well W1 is higher than the doped concentration of the substrate 110.

The wells W2A and W2B are disposed on the deep well 120 and have the second conductivity type. In this case, the doped region 130A is disposed in the well W2A, and the doped region 130B is disposed in the well W2B. In some embodiments, the doped concentrations of the wells W2A and W2B are higher than the doped concentration of the deep well 120.

The wells W3A and W3B are disposed in the substrate 110 and have the first conductivity type. In this case, the doped region 140A is disposed in the well W3A, and the doped region 140B is disposed in the well W3B. In one embodiment, the wells W3A and W3B form a ring-shaped structure. In some embodiments, the doped concentrations of the wells W3A and W3B are similar to the doped concentration of the well W1.

In other embodiments, the ESD structure 100 further comprises interconnection structures 150 and 160. The interconnection structure 150 is electrically connected to the doped region P1 and an input-output pad IO_1. The interconnection structure 160 is electrically connected to the doped regions 140A and 140B, and an input-output pad IO_2. In a normal operation (not ESD event), the input-output pad IO_1 receives an operation voltage VH, and the input-output pad IO_2 receives another operation voltage VL. The operation voltage VH may be higher than the operation voltage VL. In the normal operation, there is no voltage to be applied to the doped regions 130A and 130B.

FIG. 1C is an equivalent circuit of an exemplary embodiment of the ESD structure according to various aspects of the present disclosure. The ESD structure 100 comprises transistors PNP_1A, PNP_2A, and a resistor R_120. The emitters of the transistors PNP_1A and PNP_2A are coupled to the interconnection structure 150. The collectors of the transistors PNP_1A and PNP_2A are coupled to the interconnection structure 160. The bases of the transistors PNP_1A and PNP_2A are coupled to the resistor R_120. In one embodiment, the resistor R_120 is an equivalent resistor of the deep well 120.

Refer to FIG. 1B, the doped region P1 and the well W1 serve as the emitters of the transistors PNP_1A and PNP_2A. The wells W2A and W2B, and the deep well 120 serve as the base of the transistor PNP_1A. The doped regions 140A and 140B, and the wells W3A and W3B serve as the collector of the transistor PNP_1A. Furthermore, the deep well 120 serves as the base of the transistor PNP_2A. The substrate 110, the wells W3A and W3B, and the doped regions 140A and 14B serve as the collector of the transistor PNP_2A. When a first ESD event occurs on the input-output pad IO_1 and the input-output pad IO_2 receives a ground voltage, the transistors PNP_1A and PNP_2A are turned on. Therefore, a first ESD current passes through the transistors PNP_1A and PNP_2A from the input-output pad IO_1 and enters the input-output pad IO_2.

FIG. 1D is an equivalent circuit of another exemplary embodiment of the ESD structure according to various aspects of the present disclosure. The ESD structure 100 comprises transistors PNP_1B and PNP_2B, and the resistor R_120. The emitters of the transistors PNP_1B and PNP_2B are coupled to the interconnection structure 160. The collectors of the transistors PNP_1B and PNP_2B are coupled to the interconnection structure 150. The bases of the transistors PNP_1B and PNP_2B are coupled to the resistor R_120. In one embodiment, the resistor R_120 is an equivalent resistor of the deep well 120.

Refer to FIG. 1B, the doped region P1 and the well W1 serve as the collectors of the transistors PNP_1B and PNP_2B. The wells W2A and W2B, and the deep well 120 serve as the base of the transistor PNP_1B. The doped regions 140A and 140B, and the wells W3A and W3B serve as the emitter of the transistor PNP_1B. Furthermore, the deep well 120 serves as the base of the transistor PNP_2B. The substrate 110, the wells W3A and W3B, and the doped regions 140A and 14B serve as the emitter of the transistor PNP_2B. When a second ESD event occurs on the input-output pad IO_2 and the input-output pad IO_1 receives a ground voltage, the transistors PNP_1B and PNP_2B are turned on. Therefore, a second ESD current passes through the transistors PNP_1B and PNP_2B from the input-output pad IO_2 and enters the input-output pad IO_1.

In this embodiment, regardless of whether the ESD event occurs in the input-output pad IO_1 or IO_2, the ESD structure 100 can discharge the ESD current from the input-output pad IO_1 or IO_2. Therefore, the ESD structure 100 is a bi-directional protection element.

In other embodiment, the ESD structure 100 further comprises wells W4, W5A, W5B, W6A, and W6B. The well W4 is disposed in the well W1 and has the first conductivity type. In this case, the doped region P1 is disposed in the well W4. In one embodiment, the doped concentration of the doped region P1 is higher than the doped concentration of the well W4, and the doped concentration of the well W4 is higher than the doped concentration of the well W1.

The well W5A is disposed on the well W2A and have the second conductivity type. The well W5B is disposed on the well W2B and have the second conductivity type. In this case, the doped region 130A is disposed in the well W5A, and the doped region 130B is disposed in the well W5B. In some embodiments, the doped concentrations of the doped regions 130A and 130B are higher than the doped concentrations of the wells W5A and W5B, and the doped concentrations of the wells W5A and W5B are higher than the doped concentrations of the wells W2A and W2B.

The well W6A is disposed in the well W3A and have the first conductivity type. The well W6B is disposed in the well W3B and have the first conductivity type. In this case, the doped region 140A is disposed in the well W6A, and the doped region 140B is disposed in the well W6B. In one embodiment, the wells W6A and W6B form a ring-shaped structure. In some embodiments, the doped concentrations of the doped regions 140A and 140B are higher than the doped concentrations of the wells W6A and W6B, and the doped concentrations of the wells W6A and W6B are higher than the doped concentrations of the wells W3A and W3B.

Refer to FIG. 1A, FIG. 1A only shows the doped regions P1, 130A, 130B, 140A, and 140B shown in FIG. 1B. For brevity, other structures shown in FIG. 1B are omitted in FIG. 1A. In FIG. 1A, the floating structure 130 comprises a region AR1. The doped region P1 is disposed in the region AR1. In this case, the floating structure 130 surrounds the doped region P1. In this embodiment, the voltage level of the floating structure 130 is a floating level. The floating structure 130 comprises the doped regions 130A and 130B. The ring-shaped structure 140 surrounds the floating structure 130. In this embodiment, the ring-shaped structure 140 comprises the doped regions 140A and 140B.

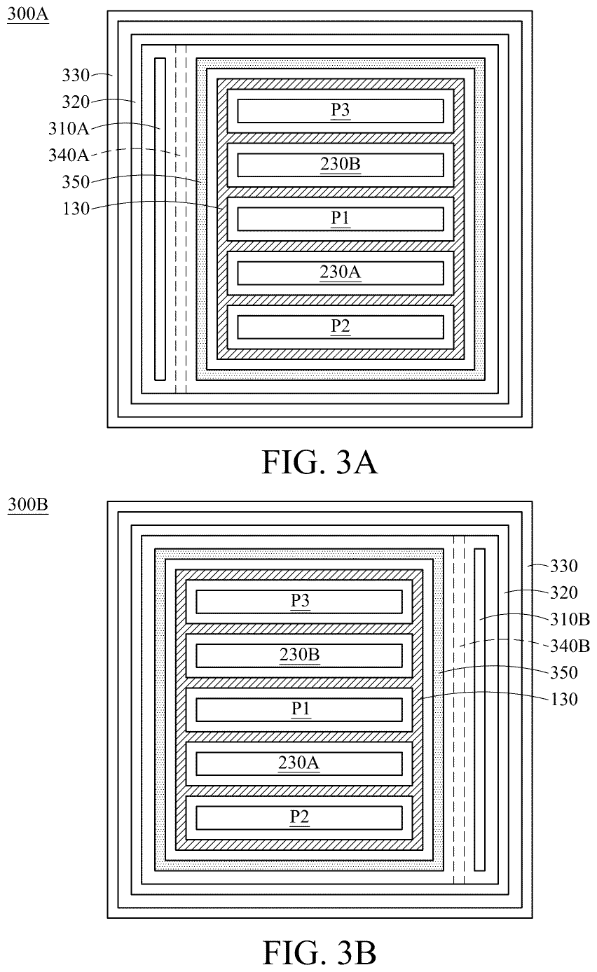

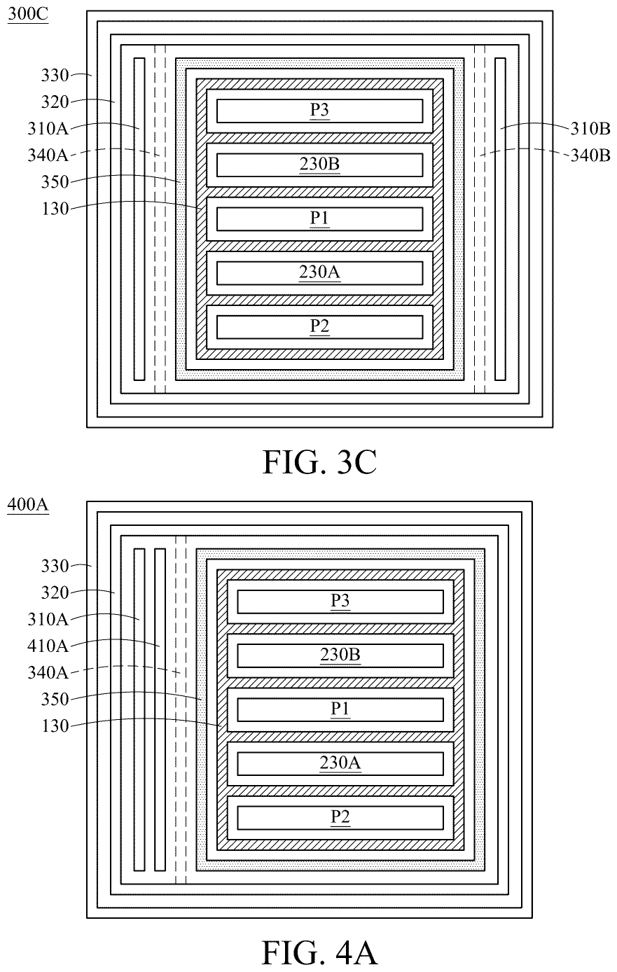

FIG. 2A is a plan view of another exemplary embodiment of the ESD structure in accordance with some embodiments of the disclosure. FIG. 2B is a cross-sectional view taken alone a line B-B′ of FIG. 2A. As shown in FIG. 2B, the ESD structure 200 comprises a substrate 210 and a deep well 220. The substrate 210 has the first conductivity type. The deep well 220 is disposed in the substrate 210 and has the second conductivity type.

In addition to the doped regions P1, 130A, 130B, 140A, and 140B, the ESD structure 200 further comprises doped regions P2, P3, 230A, 230B, 240A, 240B, 250A, and 250B. The doped regions P2, P3, 230A, 230B, 240A, 240B, 250A, and 250B are disposed on the deep well 220 and have the first conductivity type. In one embodiment, the doped concentrations of the doped regions P2, P3, 230A, 230B, 240A, 240B, 250A, and 250B are similar to the doped concentration of the doped region P1.

In this embodiment, the doped regions 130A, 130B, 240A, 240B, 250A, and 250B form the floating structure 130. The floating structure 130 does not receive any voltage. Therefore, the voltage level of the floating structure 130 is a floating level. In some embodiments, the doped regions P1~P3 are electrically connected to the interconnection structure 150, and the doped regions 140A, 140B, 230A, and 230B are electrically connected to the interconnection structure 160.

In some embodiments, the ESD structure 200 further comprises wells W7, W8, 261A, 261B, 271A, 271B, 281A, and 281B. The wells W7, W8, 261A, and 261B are disposed on the deep well 220 and have the first conductivity type. In this case, the doped region 230A is disposed in the well 261A, and the doped region 230B is disposed in the well 261B. The doped region P2 is disposed in the well W7. The doped region P3 is disposed in the well W8. In one embodiment, the doped concentrations of the wells W7, W8, 261A, and 261B are similar to the doped concentration of the well W1.

The wells 271A, 271B, 281A, and 281B are disposed on the deep well 220 and have the second conductivity type. In this case, the doped region 240A is disposed in the well 281A, and the doped region 240B is disposed in the well 271A. The doped region 250A is disposed in the well 271B, and the doped region 250B is disposed in the well 281B. In one embodiment, the doped concentrations of the well 271A, 271B, 281A, and 281B are similar to the doped concentration of the well W2A.

In other embodiments, the ESD structure 200 further comprises wells W9, W10, 262A, 262B, 272A, 272B, 282A, and 282B. The wells W9, W10, 262A, and 262B are disposed on the deep well 220 and have the first conductivity type. In this case, the well W9 is disposed in the well W7. Furthermore, the well W10 is disposed in the well W8. The well 262A is disposed in the well 261A. The well 262B is disposed in the well 261B. The doped concentrations of the wells W9, W10, 262A, and 262B are higher than the doped concentrations of the wells W7, W8, 261A, and 261B. In some embodiments, the doped region P2 is disposed in the well W9, the doped region P3 is disposed in the well W10, the doped region 230A is disposed in the well 262A, and the doped region 230B is disposed in the well 262B. In this case, the doped concentrations of the wells W9, W10, 262A, and 262B are lower than the doped concentration of the doped regions P2, P3, 230A, and 230B.

The wells 272A, 272B, 282A, and 282B are disposed on the deep well 220 and have the second conductivity type. In this case, the well 272A is disposed in the well 271A, the well 272B is disposed in the well 271B, the well 282A is disposed in the well 281A, and the well 282B is disposed in the well 281B. The doped concentrations of the wells 272A, 272B, 282A, and 282B are higher than the doped concentrations of the wells 271A, 271B, 281A, and 281B. In some embodiments, the doped region 240B is disposed in the well 272A, the doped region 250a is disposed in the well 272B, the doped region 2401 is disposed in the well 282A, and the doped region 250B is disposed in the well 282B.

Refer to FIG. 2A, FIG. 2A only shows the doped regions P1~P3, 230A, and 230B shown in FIG. 1B. For brevity, other structures shown in FIG. 2B are omitted in FIG. 2A. The floating structure 130 surrounds the doped regions P1~P3, 230A, and 230B. In this embodiment, the voltage level of the floating structure 130 is a floating level. The floating structure 130 comprises the doped regions 130A, 130B, 240A, 240B, 250A, and 250B. The ring-shaped structure 140 surrounds the floating structure 130. In this embodiment, the ring-shaped structure 140 comprises the doped regions 140A and 140B.

In some embodiment, the floating structure 130 comprises regions AR1~AR5. The doped region P1 is disposed in the region AR1. The doped region 230A is disposed in the region AR2. The doped region 230B is disposed in the region AR3. The doped region P2 is disposed in the region AR4. The doped region P3 is disposed in the region AR5. Additionally, the doped region P1 is disposed between the doped regions 230A and 230B. The doped region 230A is disposed between the doped regions P1 and P2. The doped region 230B is disposed between the doped regions P1 and P3.

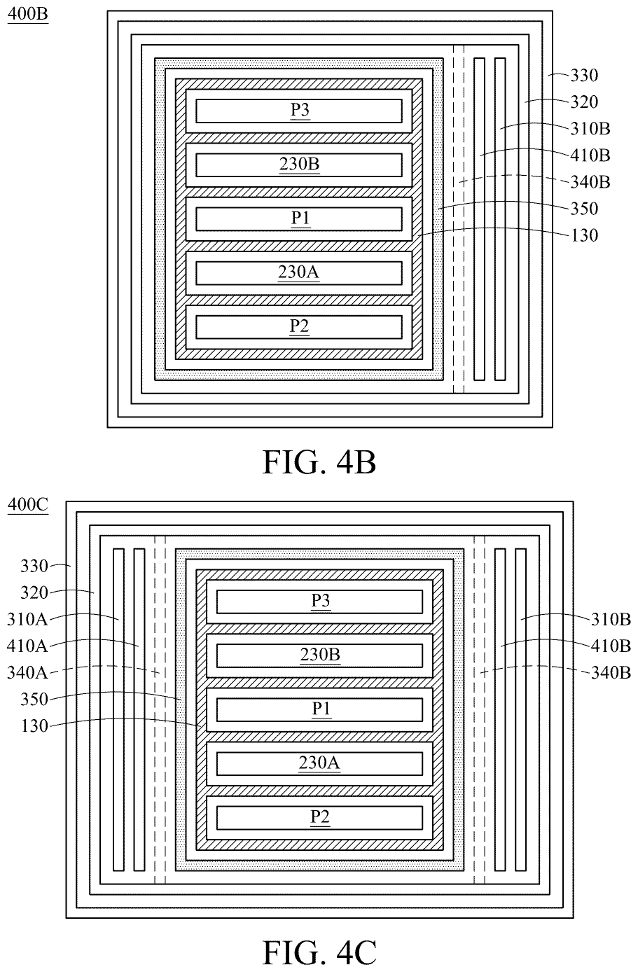

FIG. 3A is a plan view of another exemplary embodiment of the ESD structure in accordance with some embodiments of the disclosure. FIG. 3A is similar to FIG. 2A with the exception that the ESD structure 300A further comprises a doped region 310A, a floating structure 320, and a ring-shaped structure 330. The doped region 310A is disposed in the left-side of the ring-shaped structure 350. The ring-shaped structure 350 is similar to the ring-shaped structure 140 shown in FIG. 2A with the exception that the ring-shaped structure 140 of FIG. 2A is disposed in the substrate 110, and the ring-shaped structure 350 of FIG. 3A is disposed on a deep well (similar to the deep well 120 of FIG. 2B). Since the characteristic of the ring-shaped structure 350 is similar to the characteristic of the ring-shaped structure 140, the related description is omitted here.

The conductivity type of the doped region 310A may be the same as or different from the conductivity type of the ring-shaped structure 350. The floating structure 320 surrounds the doped region 310A and the ring-shaped structure 350 and has the second conductivity type. In this embodiment, the voltage level of the ring-shaped structure 350 is a first floating level, and the voltage level of the floating structure 320 is a second floating level. The ring-shaped structure 330 surrounds the floating structure 320 and has the first conductivity type. In this embodiment, the ring-shaped structure 330 serves as an electrical contact terminal of a substrate (not shown).

In some embodiments, the ESD structure 300A further comprises a floating structure 340A. The floating structure 340A is disposed between the doped region 310A and the ring-shaped structure 350 and has the first conductivity type. In this case, the floating structure 340A contacts the floating structure 320. Therefore, the voltage level of the floating structure 340A is similar to the voltage level of the floating structure 320.

FIG. 3B is a plan view of another exemplary embodiment of the ESD structure in accordance with some embodiments of the disclosure. FIG. 3B is similar to FIG. 2A with the exception that the ESD structure 300B further comprises a doped region 310B, a floating structure 320, and a ring-shaped structure 330. The doped region 310B is disposed in the right-side of the ring-shaped structure 350. The conductivity type of the doped region 310B may be the same as or different from the conductivity type of the ring-shaped structure 350. Since the characteristics of the floating structure 320 and the ring-shaped structure 330 were previously described, as such descriptions are omitted for brevity. In some embodiments, the ESD structure 300B further comprises a floating structure 340B. The floating structure 340B is disposed between the doped region 310B and the ring-shaped structure 350 and has the first conductivity type. The floating structure 340B contacts the floating structure 320. Therefore, the voltage level of the floating structure 340B is the same as the voltage level of the floating structure 320.

FIG. 3C is a plan view of another exemplary embodiment of the ESD structure in accordance with some embodiments of the disclosure. FIG. 3C is similar to FIG. 3A with the exception that the ESD structure 300C further comprises a doped region 310B. The conductivity type of the doped region 310B may be the same as or different from the conductivity type of the doped region 310A. Since the characteristic of the doped region 310B was previously described, as such descriptions are omitted for brevity. In other embodiments, the doped regions P2, P3, 230A and 230B surrounded by the floating structure 130 can be omitted.

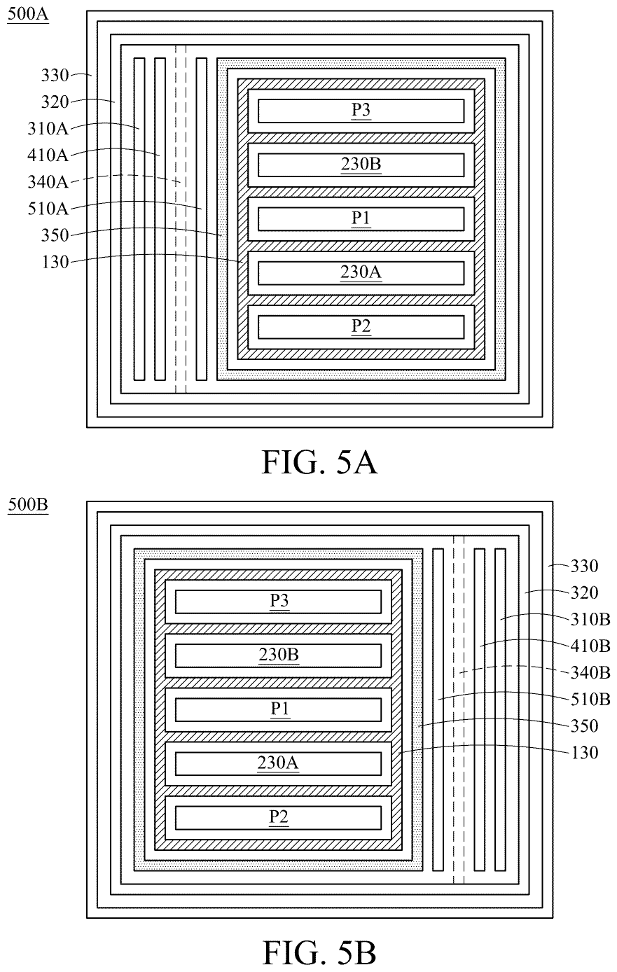

FIG. 4A is a plan view of another exemplary embodiment of the ESD structure in accordance with some embodiments of the disclosure. FIG. 4A is similar to FIG. 3A with the exception that the ESD structure 400A further comprises a doped region 410A. In this embodiment, the doped region 410A is disposed between the doped region 310A and the floating structure 340A, but the disclosure is not limited thereto. In another embodiment, the doped region 410A is disposed between the floating structure 340A and the ring-shaped structure 350. The conductivity type of the doped region 410A may be the same as or different from the conductivity type of the doped region 310A. In some embodiments, the floating structure 340A is omitted.

FIG. 4B is a plan view of another exemplary embodiment of the ESD structure in accordance with some embodiments of the disclosure. FIG. 4B is similar to FIG. 3B with the exception that the ESD structure 400B further comprises a doped region 410B. In this embodiment, the doped region 410B is disposed between the doped region 310B and the floating structure 340B, but the disclosure is not limited thereto. In another embodiment, the doped region 410B is disposed between the ring-shaped structure 350 and the doped region 410B. The conductivity type of the doped region 410B may be the same as or different from the conductivity type of the doped region 310B. In some embodiments, the floating structure 340B is omitted.

FIG. 4C is a plan view of another exemplary embodiment of the ESD structure in accordance with some embodiments of the disclosure. FIG. 4C is similar to FIG. 4A with the exception that the ESD structure 400C further comprises a doped region 410B. The conductivity type of the doped region 410B may be the same as or different from the conductivity type of the doped region 410A. Since the characteristic of the doped region 410B was previously described, as such descriptions are omitted for brevity. In other embodiments, the doped regions P2, P3, 230A and 230B surrounded by the floating structure 130 shown in FIG. 4A~4C can be omitted.

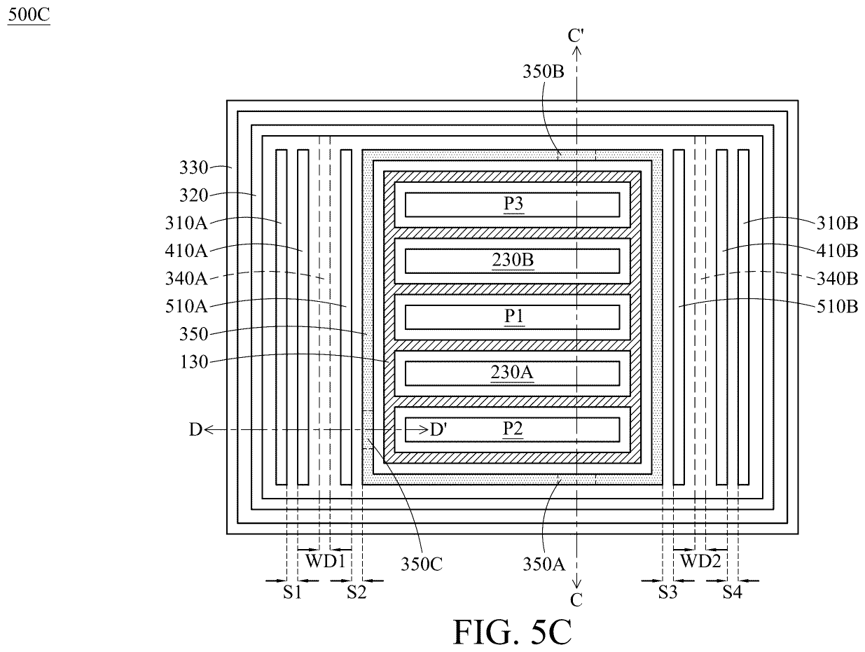

FIG. 5A is a plan view of another exemplary embodiments of the ESD structure in accordance with some embodiments of the disclosure. FIG. 5A is similar to FIG. 4A with the exception that the ESD structure 500A further comprises a doped region 510A. The doped region 510A is disposed between the floating structure 340A and the ring-shaped structure 350. The conductivity type of the doped region 510A may be the same as or different from the conductivity type of one of the ring-shaped structure 350, the doped regions 310A and 410A.

FIG. 5B is a plan view of another exemplary embodiments of the ESD structure in accordance with some embodiments of the disclosure. FIG. 5B is similar to FIG. 4B with the exception that the ESD structure 500B further comprises a doped region 510B. The conductivity type of the doped region 510B may be the same as or different from the conductivity type of one of the ring-shaped structure 350, the doped region 310B and the doped region 410B.

FIG. 5C is a plan view of another exemplary embodiments of the ESD structure in accordance with some embodiments of the disclosure. FIG. 5C is similar to FIG. 5A with the exception that the ESD structure 500C further comprises a doped region 510B. Since the characteristic of the doped region 510B was previously described, as such descriptions are omitted for brevity. In this embodiment, there is a distance S1 between the doped regions 310A and 410A, there is a distance S2 between the doped region 510A and the ring-shaped structure 350, there is a distance S3 between the doped region 510B and the ring-shaped structure 350, and there is a distance S4 between the doped regions 410B and 310B. In one embodiment, the distances S1~S4 are equal to each other. In another embodiment, at least one of the distances S1~S4 is different from the other of the distances S1~S4. In other embodiment, the width WD1 of the floating structure 340A may be the same as or different from the width WD2 of the floating structure 340B. In other embodiments, the doped regions P2, P3, 230A, and 230B in the floating structure 130 of FIG. 5A~5C can be omitted.

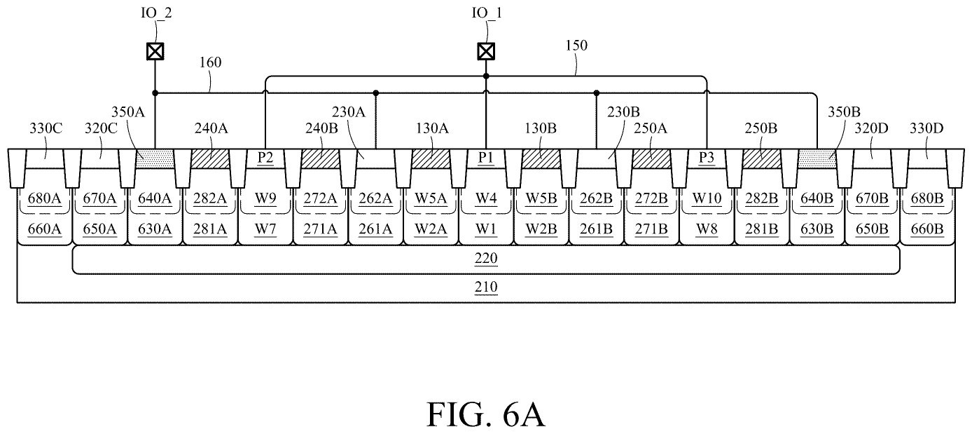

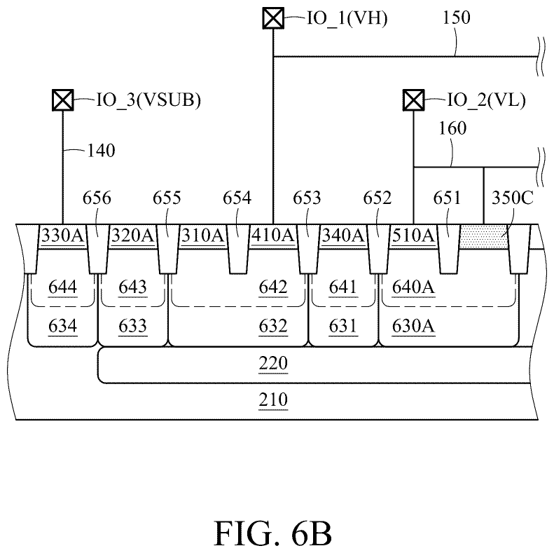

FIG. 6A is a cross-sectional view taken alone a line C-C′ of FIG. 5C. FIG. 6A is similar to FIG. 2B with the exception that the doped regions 140A and 140B of FIG. 2B are disposed in the substrate 110 and the doped regions 350A and 350B of FIG. 6A are disposed in the deep well 220. In this embodiment, the doped region 350A is disposed in the well 640A, and the well 640A is disposed in the well 630A. The well 640A is disposed on the deep well 220. The doped concentration of the doped region 350A is higher than the doped concentration of the well 640A, and the doped concentration of the well 640A is higher than the doped concentration of the well 630A. In some embodiments, the doped concentration of the of the well 640A is similar to the doped concentration of the well W4, and the doped concentration of the doped region 630A is similar to the doped concentration of the well W1.

The doped region 350B is disposed in the well 640B. The well 640B is disposed i the well 630B. The well 640B is disposed on the deep well 220. In one embodiment, the doped concentration of the doped region 350B is higher than the doped concentration of the well 640B, and the doped concentration of the well 640B is higher than the doped concentration of the well 630B. In some embodiments, the doped concentration of the well 640B is similar to the doped concentration of the well W4, and the doped concentration of the well 630B is similar to the doped concentration of the well W1.

The ESD structure 500C further comprises wells 650A, 650B, 660A, and 660B. The wells 650A and 650B are disposed on the deep well 220 and have the second conductivity type. In this case, the doped region 320C is disposed in the well 650A, and the doped region 320D is disposed in the well 650B. The doped regions 320C and 320D are part of the floating structure 320 and have the second conductivity type. The doped concentrations of the doped regions 320C and 320D are higher than the doped concentrations of the wells 650A and 650B.

The wells 660A and 660B are disposed in the substrate 210 and have the first conductivity type. The wells 660A and 660B serve as electrical contact terminals of the substrate 210. In this case, the doped region 330C is disposed in the well 660A, and the doped region 330D is disposed in the well 660B. The doped regions 330C and 330D are part of the ring-shaped structure 330 and have the first conductivity type. The doped concentration s of the doping regions 330C and 330D are similar to the doped concentration of the doping region P1 and higher than the doped concentration s of the wells 660A and 660B.

In some embodiments, the ESD structure 500C further includes wells 670A, 670B, 680A, and 680B. The well 670A is disposed in the well 650A and has the second conductivity type. The well 670B is disposed in the well 650B and has the second conductivity type. The doping region 320C is disposed in well 670A. The doping region 320D is disposed in well 670B. The doped concentration s of the doping regions 320C and 320D are higher than the doped concentration s of the wells 670A and 670B. The doped concentration s of wells 670A and 670B are higher than the doped concentration s of wells 650A and 650B.

The well 680A is disposed in the well 660A and has the first conductivity type. The well 680B is disposed in the well 660B and has the first conductivity type. The doping region 330C is disposed in the well 680A. The doping region 330D is disposed in the well 680B. The doped concentration s of the doping regions 330C and 330D are higher than the doped concentration s of the wells 680A and 680B. The doped concentration of the wells 680A and 680B is higher than the doped concentration of the wells 660A and 660B.

FIG. 6B is a cross-sectional view taken alone a line D-D′ of FIG. 5C. The doped regions 350C, 510A, 340A, 410A, 310A and 320A are disposed on the deep well 220. The doped region 350C is part of ring-shaped structure 350. The doped regions 510A and 350C are electrically connected to the interconnect structure 160. The conductivity type of the doped region 510A may be the same as or different from the conductivity type of the doped region 350C. When the doped regions 510A and 350C have the same conductivity type, the doped regions 510A and 350C may be integrated into a single doped region.

The floating structure 340A has the first conductivity type. The electrical property of the floating structure 340A is a floating level. In one embodiment, the doped concentration of the floating structure 340A is similar to the doped concentration of the doping region P1. The doped regions 410A and 310A are electrically connected to the interconnect structure 150. The conductivity type of the doped region 410A may be the same as or different from the conductivity type of the doped region 310A. When the doped regions 410A and 310A have the same conductivity type, the doped regions 410A and 310A may be integrated into a single doped region.

The doped region 320A has the second conductivity type. The electrical property of the doped region 320A is a floating level. In this embodiment, the doped region 320A is a part of the floating structure 320 of FIG. 5C. The doped region 330A is disposed in the substrate 210 and has the first conductivity type. The doped concentration of the doping region 330A is similar to the doped concentration of the doping region P1. In addition, the doped region 330A is electrically connected to an interconnect structure 170 and serves as an electrical contact terminal of the substrate 210. In this embodiment, the doped region 330A is a part of the ring-shaped structure 330 shown in FIG. 5C. In one embodiment, the interconnect structure 170 is electrically connected to the input-output pad IO_3 to receive an operation voltage VSUB. The operation voltage VSUB may be equal to the operation voltage VL.

In some embodiments, the ESD structure 500C further comprises wells 630A and 631~634. The wells 630A and 631~633 are disposed on the deep well 220. The well 634 is disposed in the substrate 210. In this embodiment, the doping regions 510A and 350C are disposed in the well 630A. The characteristic of the well 630A is similar to the well W3A of FIG. 2B, the related description is omitted here. The floating structure 340A is disposed in the well 631. The doped regions 410A and 310A are disposed in the well 632. The doped region 320A is disposed in the well 633. The doped region 330A is disposed in the well 634.

In one embodiment, the wells 631 and 633 have the second conductivity type, and the wells 630A, 632, and 634 have the first conductivity type. The doped concentrations of the wells 631 and 633 are similar to the doped concentration of the well W2A of FIG. 1B. The doped concentrations of the wells 630A, 632, and 634 are similar to the doped concentration of the well W3A.

In other embodiments, the ESD structure 500C further comprises the wells 640A and 641~644. The well 640A is disposed in the well 630A. The doped regions 510A and 350C are disposed in the well 640A. The conductivity type of the well 640A is the same as the conductivity type of the well 630A. In one embodiment, the doped concentration of the well 640A is higher than the doped concentration of the well 630A, and is similar to the doped concentration of the well W6A of FIG. 2B.

The well 641 is disposed in the well 631. The floating structure 340A is disposed in the well 641. The conductivity type of the well 641 is the same as the conductivity type of the well 631. In one embodiment, the doped concentration of the well 641 is higher than the doped concentration of the well 631 and is similar to the doped concentration of the well W5A of FIG. 1B.

The well 642 is disposed in the well 632. The doped regions 410A and 310A are disposed in the well 642. The conductivity type of the well 642 is the same as the conductivity type of the well 632. In one embodiment, the doped concentration of the well 642 is higher than the doped concentration of the well 632 and is similar to the doped concentration of the well W6A.

The well 643 is disposed in the well 633. The doped region 320A is disposed in the well 643. The conductivity type of the well 643 is the same as the conductivity type of the well 633. In one embodiment, the doped concentration of the well 643 is higher than the doped concentration of the well 633 and is similar to the doped concentration of the well 641. In some embodiments, the wells 633 and 643 are ring-shaped structures.

The well 644 is disposed in the well 634. The doped region 330A is disposed in the well 644. The conductivity type of the well 644 is the same as the conductivity type of the well 634. In one embodiment, the doped concentration of the well 644 is higher than the doped concentration of the well 634 and is similar to the doped concentration of the well 642. In some embodiments, the well 644 is a ring-shaped structure.

In other embodiments, the ESD structure 500C further comprises isolation structures 651~656. The isolation structure 651 is disposed in the well 640A and isolates the doped region 510A from the doped region 350C. The isolation structure 652 isolates the doped region 510A from the doped region 340A and isolates the well 640A from the well 641. The isolation structure 653 isolates the doped region 410A from the doped region 340A and isolates the well 641 from the well 642. The isolation structure 654 is disposed in the well 642 and isolates the doped region 310A from the doped region 410A. The isolation structure 655 isolates the doped region 320A from the doped region 310A and isolates the well 642 from the well 643. The isolation structure 656 isolates the doped region 330A from the doped region 320A and isolates the well 643 from the well 644.

In some embodiments, the isolation structure 653 can be omitted. In this case, the doped region 410A may contact the floating structure 340A and the well 641 may contact the well 642. Furthermore, at least one of the isolation structures 651 and 654 can be omitted. Taking the isolation structure 651 as an example, if the isolation structure 651 is omitted, the doped region 510A may contact the doped region 350C.

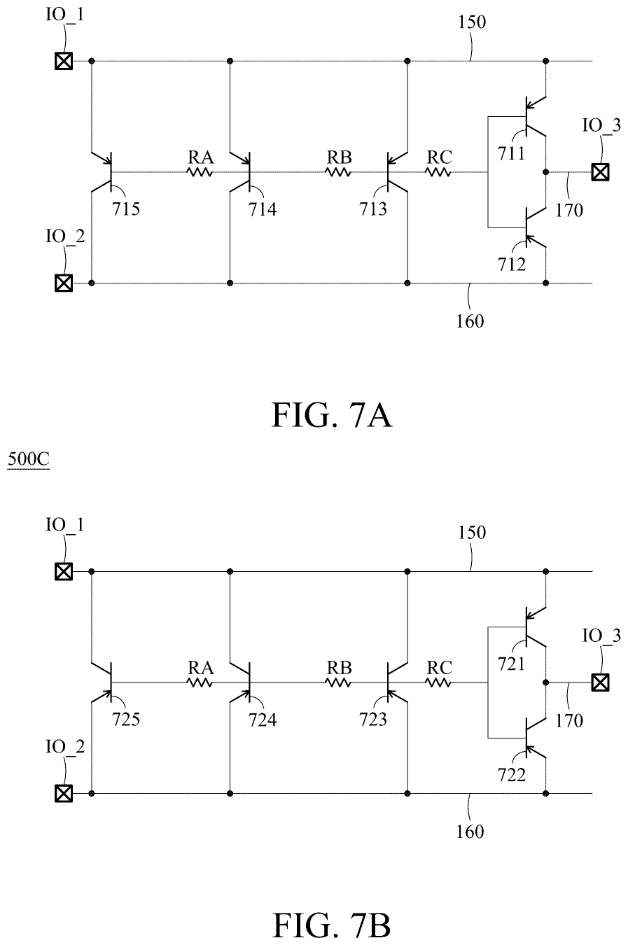

In one embodiment, the doped regions 310A, 410A, 510A and 350C are the first conductivity type. In this case, the doping concentrations of the doping regions 310A, 410A, 510A, and 350C are similar to the doping concentration of the doping region P1 of FIG. 1B. FIG. 7A is an equivalent circuit of the ESD structure 500C according to various aspects of the present disclosure, wherein the doped regions 310A, 410A, 510A, and 350C have the first doped region. The ESD structure 500C comprises transistors 711~715 and resistors RA, RB, and RC.

When an ESD event occurs in the input-output pad IO_1 and the input-output pads IO_2 and IO_3 are coupled to ground, the transistors 711~715 are turned on. At this time, part of the ESD current flows from the input-output pad IO_1, passes through the transistors 713~715, and enters the input-output pad IO_2. In addition, part of the ESD current flows from the input-output pad IO_1, passes through the transistor 711, and enters the input-output pad IO_3.

Refer to FIG. 6B, the doped regions 310A and 410A serve as the emitter of the transistor 715. The doped regions 510A and 350C serve as the collectors of the transistors 713, 714, and 715. The doped region 330A serves as the collectors of the transistors 711 and 712. The deep well 220 serves as the bases of the transistors 711~715. The resistors RA, RB, and RC are the equivalent resistor of the deep well 220. Refer to FIG. 6A, the doped region P1 serves as the emitters of the transistors 711~714.

FIG. 7B is an equivalent circuit of another exemplary embodiment of the ESD structure 500C comprising the doped regions 310A, 410A, 510A and 350C which have the first conductivity type according to various aspects of the present disclosure. The ESD structure 500C comprises transistors 721~725 and the resistors RA, RB, and RC. When an ESD events occurs in the input-output pad IO_2 and the input-output pads IO_1 and IO_3 are coupled to ground, the transistors 721~725 are turned on. At this time, part of the ESD current flows from the input-output pad IO_2, passes through the transistors 723~725, and enters the input-output pad IO_1. In addition, part of the ESD current flows from the input-output pad IO_2, passes through the transistor 722, and enters the input-output pad IO_3.

Refer to FIG. 6B, the doped regions 310A and 410A serve as the collector of the transistor 725. The doped regions 510A and 350C serve as the emitters of the transistors 723~725. The doped region 330A serves as the collectors of the transistors 721 and 722. The deep well 220 serves as the bases of the transistors 721~725. Refer to FIG. 6A, the doped region P1 serves as the emitters of the transistors 721 and 722 and the collectors of the transistors 723 and 724.

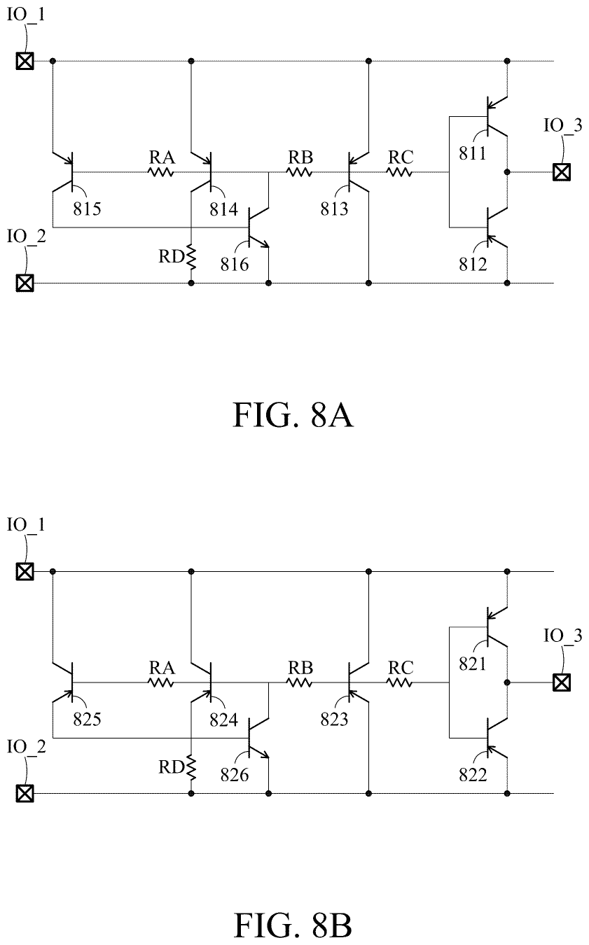

In another embodiment, the doped regions 310A and 410A have the first conductivity type. In this case, one of the doped regions 510A and 350C has the first conductivity type, and the other of the doped regions 510A and 350C has the second conductivity type. FIG. 8A is an equivalent circuit of another exemplary embodiment of the ESD structure 500C according to various aspects of the present disclosure. The ESD structure 500C comprises transistors 811~816 and the resistors RA, RB, RC, and RD. When an ESD event occurs in the input-output pad IO_1 and the input-output pads IO_2 and IO_3, the transistors 811~816 turned on. At this time, part of the ESD current flows from the input-output pad IO_1, passes through the transistors 811~816, and enters the input-output pad IO_2 or IO_3.

Refer to FIG. 6B, the doped regions 310A and 410A serve as the emitter of the transistor 815. The doped region 510A, and the wells 640A and 630A serve as the collector of the transistor 815. The well 631 and the deep well 220 serve as the base of the transistor 815. The doped region 350C serves as the emitter of the transistor 816. The wells 640A and 630A serve as the base of the transistor 816 and the collector of the transistor 814. The deep well 220 serves as the collector of the transistor 816. Additionally, the resistor RD is the equivalent resistor of the well 640A. The deep well 220 serves as the bases of the transistors 811~814. The doped region 330A serves as the collectors of the transistors 811 and 812. Refer to FIG. 6A, the doped region P1 serves as the emitters of the transistors 811~814.

FIG. 8B is an equivalent circuit of another exemplary embodiments of the ESD structure 500C according to various aspects of the present disclosure. The ESD structure 500C comprises transistors 821~826 and the resistors RA, RB, RC, and RD. When an ESD event occurs in the input-output pad IO_2 and the input-output pads IO_1 and IO_3 are coupled to ground, the transistors 821~826 are turned on. At this time, part of the ESD current flows from the input-output pad IO_2, passes through the transistors 821~826, and enters the input-output pad IO_1 or IO_3.

Refer to FIG. 6B, the doped regions 310A and 410A serve as the collector of the transistor 825. The doped region 510A, and the wells 640A and 630A serve as the emitter of the transistor 825. The well 631 and the deep well 220 serve as the base of the transistor 825. The doped region 350C serves as the emitter of the transistor 826. The wells 640A and 630A serve as the base of the transistor 826 and the emitter of the transistor 824. The deep well 220 serves as the collector of the transistor 826. Additionally, the resistor RD is the equivalent resistor of the well 640A. The deep well 220 serves as the bases of the transistors 821~824. The doped region 330A serves as the collectors of the transistors 821 and 822. Refer to FIG. 6A, the doped region P1 serves as the emitters of the transistors 821~824.

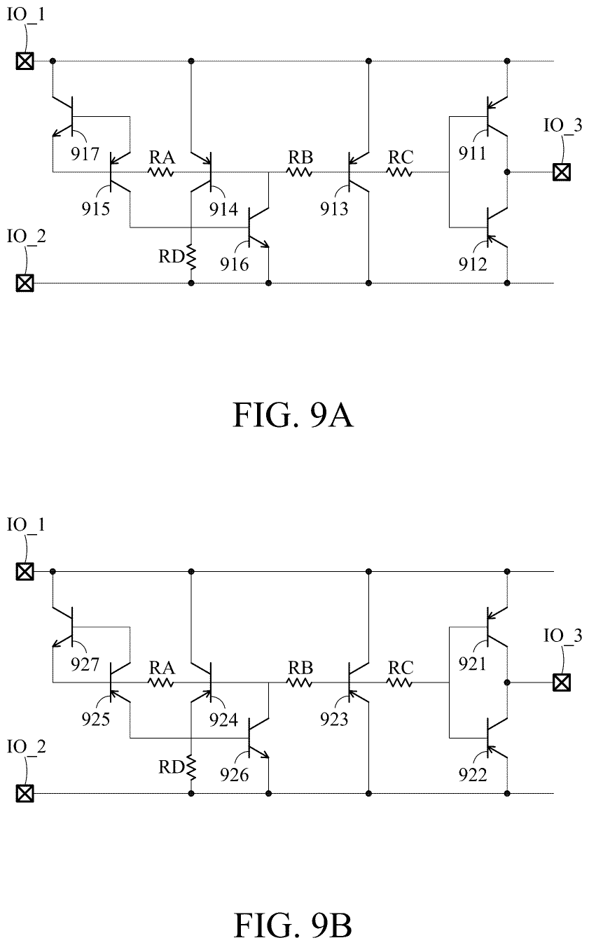

In another embodiment, the doped regions 310A and 410A have the second conductivity type. In this case, the doped regions 510A and 350C have the second conductivity type or one of the doped regions 510A and 350C has the first conductivity type, and the other of the doped regions 510A and 350C has the second conductivity type. FIGS. 9A and 9B are equivalent circuits of other exemplary embodiments of the ESD structure 500C according to various aspects of the present disclosure.

Refer to FIG. 9A, the ESD structure 500C comprises transistors 911~917 and the resistors RA, RB, RC, and RD. When an ESD event occurs in the input-output pad IO_1 and the input-output pads IO_2 and IO_3, the transistors 911~917 are turned on. At this time, part of the ESD current flows from the input-output pad IO_1, passes through the transistors 911~917, and enters the input-output pad IO_2 or IO_3.

Since the structures of the transistors 911~916 and the resistors RA, RB, RC and RD shown in FIG. 9A are similar to the structures of the transistors 811~816 and the resistors RA, RB, RC and RD shown in FIG. 8A, the related description is omitted here. Refer to FIG. 6B, the doped region 410A serves as the emitter of the transistor 917. The wells 642 and 632 serve as the base of the transistor 917. The deep well 220 serves as the collector of the transistor 917.

Refer to FIG. 9B, the ESD structure 500C comprises transistors 921~927 and the resistors RA, RB, RC, and RD. When an ESD event occurs in the input-output pad IO_2 and the input-output pads IO_1 and IO_3, the transistors 921~927 are turned on. At this time, part of the ESD current flows from the input-output pad IO_2, passes through the transistors 921~927, and enters the input-output pad IO_1 or IO_3.

Since the structures of the transistors 921~926 and the resistors RA, RB, RC and RD shown in FIG. 9B are similar to the structures of the transistors 821~826 and the resistors RA, RB, RC and RD shown in FIG. 8B, the related description is omitted here. Since the structure of the transistor 927 Shown in FIG. 9B is similar to the structure of the transistor 917 shown in FIG. 9A, the related description is omitted here.

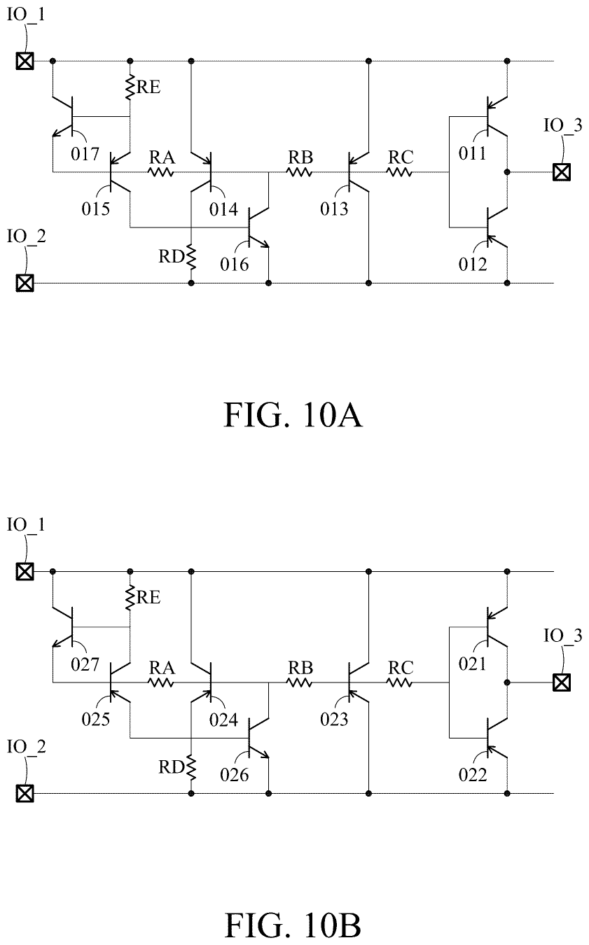

In another embodiment, the conductivity type of the doped region 310A is different from the conductivity type of the doped region 410A, and the conductivity type of the doped region 510A is different from the conductivity type of the doped region 350C. In this case, FIGS. 10A and 10B are equivalent circuits of other exemplary embodiments of the ESD structure 500C according to various aspects of the present disclosure. Refer to FIG. 10A, the ESD structure 500C comprises transistors 011~017 and the resistors RA, RB, RC, RD, and RE. When an ESD event occurs in the input-output pad IO_1 and the input-output pads IO_2 and IO_3, the transistors 011~017 are turned on. At this time, part of the ESD current flows from the input-output pad IO_1, passes through the transistors 011~017, and enters the input-output pad IO_2 or IO_3. Since the structures of the transistors 011~017 and the resistors RA, RB, RC and RD shown in FIG. 10A are similar to the structures of the transistors 921~927 and the resistors RA, RB, RC and RD shown in FIG. 9A, the related description is omitted here. Refer to FIG. 6B, the resistor RE is the equivalent resistors of the wells 642 and 632.

Refer to FIG. 10B, when an ESD event occurs in the input-output pad IO_2 and the input-output pads IO_1 and IO_3, the transistors 021~027 are turned on. At this time, part of the ESD current flows from the input-output pad IO_2, passes through the transistors 021~027, and enters the input-output pad IO_1 or IO_3.

It will be understood that when an element or layer is referred to as being “connected to” or “coupled to” another element or layer, it can be directly connected or coupled to the other element or layer or intervening elements or layers may be present. In contrast, when an element or layer is referred to as be “directly connected to” or “directly coupled to” another element or layer, there are no intervening elements or layers present.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein. It will be understood that although the terms “first,” “second,” etc. may be used herein to describe various elements, these elements should not be limited by these terms. These terms are only used to distinguish one element from another. In the following claims, the terms “first,” “second,” etc. are used merely as labels, and are not intended to impose numerical requirements on their objects.

While the invention has been described by way of example and in terms of the preferred embodiments, it should be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. An electrostatic discharge structure, comprising:
a substrate having a first conductivity type;
a deep well disposed in the substrate and having a second conductivity type;
a first doped region disposed on the deep well and having the first conductivity type;
a first floating structure disposed on the deep well, comprising a first region and having the first conductivity type;
a first ring-shaped structure surrounding the first floating structure;
a first interconnection structure electrically connected to the first doped region; and
a second interconnection structure electrically connected to the first ring-shaped structure,
wherein:
the first doped region is disposed in the first region, and the voltage level of the first floating structure is a first floating level.

2. The ESD structure as claimed in claim 1, further comprising:
a first well disposed on the deep well and having the first conductivity type,
wherein the first doped region is disposed in the first well.

3. The ESD structure as claimed in claim 2, further comprising:
a second doped region disposed on the deep well, electrically connected to the second interconnection structure, and having the first conductivity type;
a third doped region disposed on the deep well, electrically connected to the second interconnection structure, and having the first conductivity type;
a fourth doped region disposed on the deep well, electrically connected to the first interconnection structure, and having the first conductivity type; and
a fifth doped region disposed on the deep well, electrically connected to the first interconnection structure, and having the first conductivity type,
wherein:
the first floating structure comprises a second region, a third region, a fourth region and a fifth region,
the second doped region is disposed in the second region, the third doped region is disposed in the third region, the fourth doped region is disposed in the fourth region, and the fifth doped region is disposed in the fifth region.

4. The ESD structure as claimed in claim 3, wherein the first doped region is disposed between the second doped region and the third doped region.

5. The ESD structure as claimed in claim 4, wherein the second doped region is disposed between the first doped region and the fourth doped region, and the third doped region is disposed between the first doped region and the fifth doped region.

6. The ESD structure as claimed in claim 3, further comprising:
a second well disposed on the deep well and having the second conductivity type,
wherein the first floating structure is disposed on the second well.

7. The ESD structure as claimed in claim 6, wherein the second well surrounds the first well.

8. The ESD structure as claimed in claim 6, further comprising:
a third well disposed on the deep well and having the first conductivity type; and
a fourth well disposed on the deep well and having the first conductivity type,
wherein the second doped region is disposed in the third well, and the third doped region is disposed in the fourth well.

9. The ESD structure as claimed in claim 8, wherein the second well surrounds the third well and the fourth well.

10. The ESD structure as claimed in claim 9, wherein the first ring-shaped structure is disposed in the substrate, surrounds the first floating structure, and has the first conductivity type.

11. The ESD structure as claimed in claim 1, wherein the first ring-shaped structure is disposed in the deep well, surrounds the first ring-shaped structure, and has the first conductivity type.

12. The ESD structure as claimed in claim 11, further comprising:
a sixth doped region disposed in the deep well;
a second floating structure disposed in the deep well and having the second conductivity type; and
a second ring-shaped structure disposed in the substrate and having the first conductivity type,
wherein:
the voltage level of the second floating structure is a second floating level,
the second floating structure surrounds the sixth doped region and the first ring-shaped structure,
the second ring-shaped structure surrounds the second floating structure.

13. The ESD structure as claimed in claim 12, wherein the conductivity type of the sixth doped region is the same as the conductivity type of the first ring-shaped structure.

14. The ESD structure as claimed in claim 12, wherein the conductivity type of the sixth doped region is different from the conductivity type of the first ring-shaped structure.

15. The ESD structure as claimed in claim 12, further comprising:
a third floating structure disposed between the sixth doped region and the first ring-shaped structure and having the first conductivity type.

16. The ESD structure as claimed in claim 15, further comprising:
a seventh doped region disposed in the deep well and disposed between the sixth doped region and the third floating structure.

17. The ESD structure as claimed in claim 16, wherein the conductivity type of the sixth doped region is the same as the conductivity type of the seventh doped region.

18. The ESD structure as claimed in claim 16, wherein the conductivity type of the sixth doped region is different from the conductivity type of the seventh doped region.

19. The ESD structure as claimed in claim 16, further comprising:
an eighth doped region disposed in the deep well and disposed between the first ring-shaped structure and the third floating structure.

20. The ESD structure as claimed in claim 19, wherein the conductivity type of the eighth doped region is different from the conductivity type of the first ring-shaped structure, and the conductivity type of the sixth doped region is different from the conductivity type of the seventh doped region.
